(19) United States
(12) Patent Application Publication
(10) Pub. No.: US 2026/0017439 A1
(43) Pub. Date: Jan. 15, 2026

(54) METHODS AND SYSTEMS FOR OPTIMIZING AERODYNAMIC CHARACTERISTICS OF FLOW EQUALIZATION AIR RING STRUCTURES IN MEDIUM-SPEED COAL MILLS BASED ON FLUENT SIMULATION

(71) Applicant: DATANG NORTHEAST ELECTRIC POWER TEST & RESEARCH INSTITUTE CO., LTD., Changchun (CN)

(72) Inventors: Yu GU, Changchun (CN); Zengyi GU, Changchun (CN); Guipeng LI, Changchun (CN); Tiantian HAO, Changchun (CN); Qiang LI, Changchun (CN); Fuwang BAI, Changchun (CN); Jian LI, Changchun (CN); Yanhui REN, Changchun (CN); Guochao ZHAO, Changchun (CN)

(73) Assignee: DATANG NORTHEAST ELECTRIC POWER TEST & RESEARCH INSTITUTE CO., LTD., Changchun (CN)

(21) Appl. No.: 19/208,776

(22) Filed: May 15, 2025

(30) Foreign Application Priority Data
Jul. 15, 2024 (CN) 202410943158.6

(51) Int. Cl. G06F 30/28

(52) U.S. Cl. CPC G06F 30/28

(57) ABSTRACT

The present disclosure relates to a method and system for optimizing aerodynamic characteristics of a flow equalization air ring structure in a medium-speed coal mill based on Fluent simulation. The method comprises establishing and optimizing a model of the flow equalization air ring structure, meshing the model using Ansys ICEM, importing meshes, arranging an MRF rotating region on a dynamic ring structure, selecting an energy equation model, setting a DPM and a boundary condition, and adopting a modified mixture gas model based on empirical formulas for boundary conditions at an inlet and outlet, initializing computation information of a mesh node, setting a solver and performing iterative solving, after a computation result converges, performing post-processing on the computation result, storing the computation result, modifying structural parameters, and repeating the above steps to obtain a plurality of simulation results to obtain parameters of an optimal flow equalization air ring structure.

### CROSS-REFERENCE TO RELATED APPLICATIONS

This application claims priority to Chinese application No. 202410943158.6, filed on Jul. 15, 2024, the entire contents of which are incorporated herein by reference.

### TECHNICAL FIELD

The present invention relates to the technical field of structural design and computation of coal mills, and in particular, to a method and system for optimizing aerodynamic characteristics of a flow equalization air ring structure in a medium-speed coal mill based on Fluent simulation.

### BACKGROUND

With the continuous industrialization, the demand for energy in production and daily life has rapidly increased, and the installed capacity of thermal power plants has been continuously rising. As a significant part of the power generation industry, the safe operation of thermal power plants is crucial. Medium-speed coal mills are primarily used to grind bituminous coal and lean coal, which are fuels with medium hardness, providing power for coal-fired boiler units. However, due to the increasing requirements for power generation load and the emphasis on energy conservation and environmental protection, the electricity consumption rate and operational efficiency of coal mills have gradually improved.

The air ring of the coal mill, as a key component, serves the purpose of mixing primary air, drying coal powder, and transporting the coal powder into the boiler for combustion. The design quality of its structure has a significant impact on the output of the coal mill, the air-fuel ratio, and the fineness of coal powder.

The key technical challenge that needs to be addressed today is how to accurately obtain aerodynamic characteristics of a flow equalization air ring structure in a medium-speed coal mil, enhance the operational efficiency of the flow equalization air ring structure, and improve the accuracy and computational speed of existing computation manners for the flow equalization air ring structure.

### SUMMARY

The present disclosure is intended to solve technical problems in the related art, including: how to accurately obtain aerodynamic characteristics of a flow equalization air ring structure in a medium-speed coal mil, enhance the operational efficiency of the flow equalization air ring structure, and improve the accuracy and computational speed of existing computation manners for the flow equalization air ring structure, as well to resolve the issue of the imprecision in the optimization manners for the aerodynamic characteristics of the air ring flow equalization structure in the medium-speed coal mills of the current thermal power plants.

Therefore, the present disclosure provides a method for optimizing aerodynamic characteristics of a flow equalization air ring structure in a medium-speed coal mill based on Fluent simulation, the method comprising:
S1: determining a flow equalization air ring structure in a coal mill and establishing a model of the flow equalization air ring structure;
S2: meshing the model of the flow equalization air ring structure;
S3: checking meshes and setting mesh parameters;
S4: selecting an energy equation model, and setting a turbulence model and a Discrete Phase Model (DPM);
S5: setting a boundary condition;
S6: initializing computation information of a mesh node;
S7: setting a residual curve, establishing a monitoring curve based on a total mass flow rate at an inlet and outlet of a flow field, setting a total number of computation steps and computation step size of the energy equation model, and performing iterative solving to obtain a computation result;
S8: judging whether a computation process is convergent based on the residual curve, the computation result, and the total mass flow rate at the inlet and outlet of the flow field, in response to judging the computation process being convergent, performing post-processing on the computation result to obtain a distribution result of parameters of the flow field; and in response to judging the computation process being not convergent, adjusting the meshes, the energy equation model, and the boundary condition, and re-calculating until the computation process converges.
S9: storing a computation result after the computation process is convergent; and
S10: modifying parameters of the flow equalization air ring structure in the medium-speed coal miller, and after completion of modification, repeating S1 to S9 to obtain a plurality of simulation results, comparing the plurality of simulation results to obtain parameters of an optimal flow equalization air ring structure, and completing the method.

In some embodiments, in the S1, the model of the flow equalization air ring structure is established based on an outer diameter, an inner diameter, a size of a flow equalization unit, a count of the flow equalization unit, and an inlet wind angle of the flow equalization air ring structure.

In some embodiments, the S1 further includes importing the model of the flow equalization air ring structure into Ansys SpaceClaim to optimize a structure and a flow field domain model of the flow equalization air ring structure, and dividing and naming a rotating ring region and a stationary ring region of the model of the flow equalization air ring structure, respectively.

In some embodiments, the S2 includes dividing an overall flow field of the model of the flow equalization air ring structure using a tetrahedral mesh, adding a hexahedral boundary layer at a fluid near-wall region and naming different regions of the hexahedral boundary layer after addition, respectively.

In some embodiments, the checking meshes includes checking quality, size, and distribution state of the meshes; and the mesh parameters include mesh size, pressure velocity, and gravity direction.

In some embodiments, the S5 includes: setting a fluid region, and a fluid region of a dynamic ring structure is arranged with a Multiple Reference Frame (MRF) rotating region, setting a material of the MRF rotating region, properties of a wall condition, and physical parameters of an inlet and outlet.

In some embodiments, the particle distribution parameter of said DPM model is calculated using a fragmentation formula.

The present disclosure further provides a system for optimizing aerodynamic characteristics of a flow equalization air ring structure in a medium-speed coal mill based on Fluent simulation, the system comprising:
a modeling module: configured to determine a flow equalization air ring structure in a coal mill and establish a model of the flow equalization air ring structure;
a meshing module: configured to mesh the model of the flow equalization air ring structure;
a checking module: configured to check meshes and set mesh parameters;
a selection module: configured to select an energy equation model, and set a turbulence model and a Discrete Phase Model (DPM);
a condition module: configured to set a boundary condition;
an initializing module: configured to initialize computation information of a mesh node;
a computation module: configured to set a residual curve, establish a monitoring curve based on a total mass flow rate at an inlet and outlet of a flow field, set a total number of computation steps and computation step size of the energy equation model, and perform iterative solving to obtain a computation result;
a judgment module: configured to judge whether a computation process is convergent based on the residual curve, the computation result, and the total mass flow rate at the inlet and outlet of the flow field, in response to judging the computation process being convergent, perform post-processing on the computation result to obtain a distribution result of parameters of the flow field; and in response to judging the computation process being not convergent, adjust the meshes, the energy equation model, and the boundary condition, and re-calculate until the computation process converges;
a storage module: configured to save a computation result after the computation process is convergent; and
an optimization module: configured to modify parameters of the flow equalization air ring structure in the medium-speed coal miller, and after completion of modification, repeat steps of the modules to obtain a plurality of simulation results, compare the plurality of simulation results to obtain parameters of an optimal flow equalization air ring structure, and complete optimization.

The present disclosure further provides a computer device, comprising a memory and a processor. The memory stores a computer program, and when the processor executes the computer program stored in the memory, the processor executes the method for optimizing aerodynamic characteristics of a flow equalization air ring structure in a medium-speed coal mill based on Fluent simulation.

The present disclosure further provides a computer-readable storage medium. The storage medium stores a computer program, and the computer program executes steps of the method for optimizing aerodynamic characteristics of a flow equalization air ring structure in a medium-speed coal mill based on Fluent simulation.

The advantages of the present invention compared to the prior art are as follows:

1. The method provided by the present disclosure incorporates a real gas model equation during the fluid flow modeling process, ensuring that the properties of the gas are closer to the real values while flowing, which makes the computation results more accurate and suitable for use in engineering applications.

2. The method provided by the present disclosure sets a multiple reference frame (MRF) rotating region in a dynamic ring region during the air ring modeling process. Compared to the conventional moving mesh approach, this method allows iteration computation s in a fixed coordinate system without the need to dynamically update the entire fluid field, thus reducing the use of computational resources and computation time. Further, the method provided by the present disclosure can provide more accurate predictions of angular velocity and other related physical quantities.

3. The method provided by the present disclosure can be applied to the coal powder transportation scenario in thermal power plants.

### BRIEF DESCRIPTION OF THE DRAWINGS

To more clearly illustrate the technical solutions in the embodiments of the present disclosure, a brief introduction to the drawings used in the description of the embodiments or prior art is provided below. It is apparent that the drawings described below are only some of the embodiments of the present disclosure, and those skilled in the art can derive other relevant drawings based on these drawings without requiring any creative effort.

FIG. 1 is a flowchart illustrating a method for optimizing aerodynamic characteristics of a flow equalization air ring structure in a medium-speed coal mill based on Fluent simulation according to some embodiments of the present disclosure;

FIG. 2 is a schematic diagram illustrating an overview of a method for optimizing aerodynamic characteristics of a flow equalization air ring structure in a medium-speed coal mill based on Fluent simulation according to some embodiments of the present disclosure;

FIG. 3 is a schematic diagram illustrating a model of an air ring structure in a coal mill according to some embodiments of the present disclosure;

FIG. 4 is a cloud diagram illustrating a velocity distribution at an outlet of an air ring according to some embodiments of the present disclosure; and

FIG. 5 is a schematic diagram illustrating a comparison of velocity distribution at an outlet of an air ring after structure optimization according to some embodiments of the present disclosure.

### DETAILED DESCRIPTION

The following description provides specific details such as particular system structures and technologies for illustrative purposes, to facilitate a thorough understanding of the embodiments of the present application. However, those skilled in the art should understand that the present application can be implemented in other embodiments without these specific details. In other cases, detailed descriptions of well-known systems, devices, circuits, and methods are omitted to avoid unnecessary details that may hinder the description of the present application.

It should be understood that when the term “comprise” is used in the present disclosure and the appended claims, it indicates the presence of the described characteristics, entirety, steps, operations, elements, and/or components, but does not exclude the presence or addition of one or more other characteristics, entirety, steps, operations, elements, components, and/or their combinations.

It should also be understood that the terms used in the present application are for the purpose of describing specific embodiments and are not intended to limit the present application. As used in the present disclosure and the appended claims, unless otherwise clearly indicated, the singular forms “a”, “an”, and “the” are intended to include the plural forms.

The following detailed description of the technical solutions in the present application will be made with reference to the accompanying drawings of the embodiments. It is evident that the described embodiments are only part of the implementations of the present application, not all of them. Any other embodiments that a person skilled in the art could derive from the embodiments in the present application, without requiring inventive labor, fall within the scope of protection of the present application.

The following description provides many specific details to facilitate a thorough understanding of the present application. However, the present application can also be implemented in other ways different from those described here. A person skilled in the art can make similar adaptations without deviating from the essence of the present application. Therefore, the present application is not limited to the specific embodiments disclosed below.

### Embodiment 1

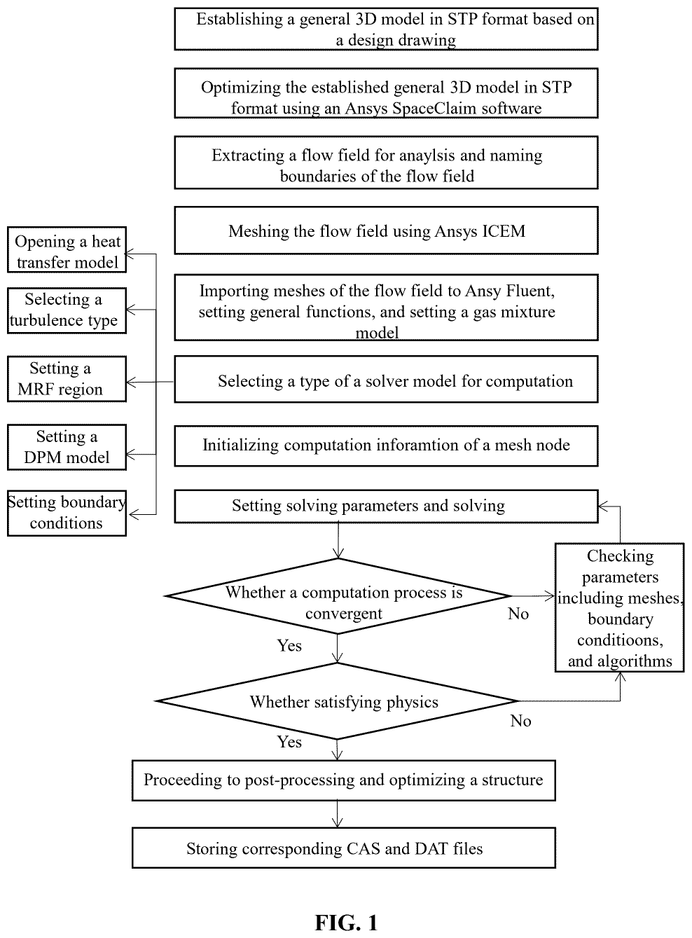

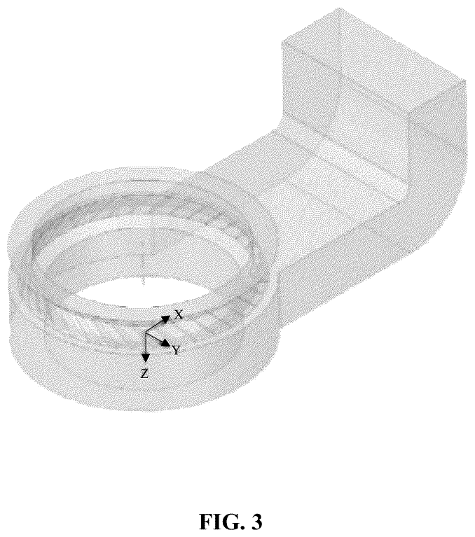

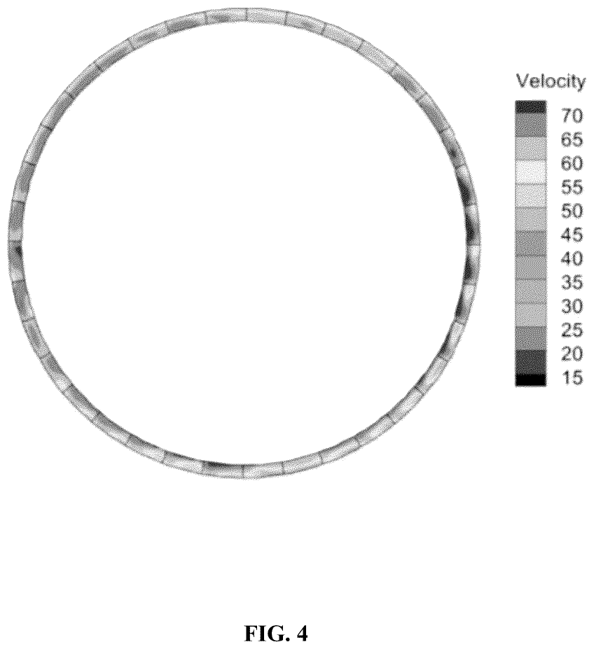

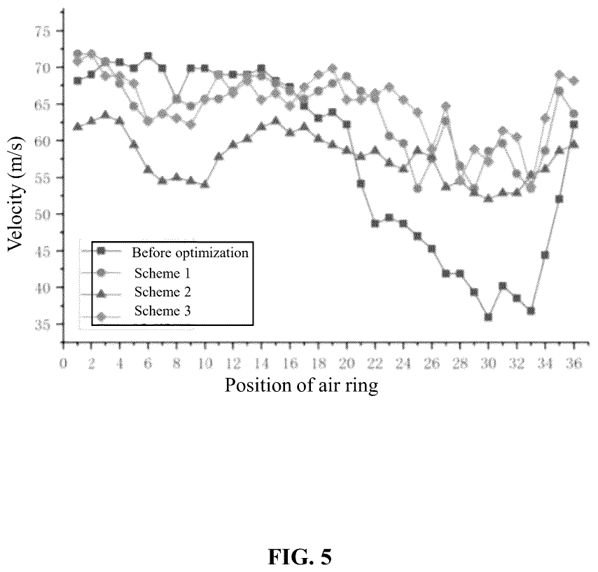

The present embodiment is described with reference to FIG. 1, FIG. 3, FIG. 4, and FIG. 5.

The present embodiment proposes a method for optimizing aerodynamic characteristics of a flow equalization air ring structure in a medium-speed coal mill based on Fluent simulation, the method comprising:

In S1: a flow equalization air ring structure in a coal mill may be determined, and based on a design scheme of the flow equalization air ring structure, a model of the flow equalization air ring structure in a medium-speed coal mill may be established using 3D modeling software, and the model of the flow equalization air ring structure may be imported into Ansys SpaceClaim to optimize a structure and a flow field domain model of the model of the flow equalization air ring structure, and a rotating ring region and a stationary ring region of the model of the flow equalization air ring structure may be divided and named, respectively. In the S1, the model of the flow equalization air ring structure may be established based on an outer diameter, an inner diameter, a size of a flow equalization unit, a count of the flow equalization unit, and an inlet wind angle of the flow equalization air ring structure. For a 3D structure model (i.e., the model of the flow equalization air ring structure) imported in the S1, chamfered structures that have minimal impact on flow field computation may be removed using a fill command, an optimized 3D structure model may be then used to perform fluid extraction operation at a fluid inlet surface and a fluid outlet surface, respectively, to form a computational fluid domain.

In S2, the model of the flow equalization air ring structure may be meshed. Specifically, the model of the flow equalization air ring structure may be meshed using Ansys ICEM, an overall flow field of the model of the flow equalization air ring structure may be divided using a tetrahedral mesh, a hexahedral boundary layer may be added at a fluid near-wall region, and a wall boundary condition may be set at a solid wall surface of the flow equalization air ring structure. For a fluid flow region, a velocity-inlet may be set. For a fluid flow outlet, a pressure-outlet may be set.

In S3: meshes may be checked, and mesh parameters may be set. Specifically, the meshes may be imported into Ansys Fluent to check mesh quality, mesh size, and distribution state of the meshes, and a dimension, pressure-velocity coupling, transient computation, and gravity direction of the meshes may be set.

In S4: an energy equation model in a solution model may be selected, a turbulence model and a discrete phase model (DPM) (i.e., DPM particle motion model) may be set, and parameters in the models may be obtained through experiments and determined using a fragmentation formula. An experimental process may involve obtaining sample coal from a coal mill at a pulverized coal furnace in a coal-fired power plant, obtaining a particle size and distribution state of coal powder by sieving and measurement, and setting corresponding parameters in the DPM based on an experimental result. In the S4, a pressure-based solution model may be selected, and a scale of the model, a magnitude and direction of gravitational acceleration, and a coupling mode for velocity and pressure may be set, and a transient computation mode may be set. The k-εturbulence model with a Re-Normalization Group (RNG) model may be selected.

In S5: a boundary condition may be set, materials of a fluid region and a multiple reference frame (MRF) rotating region may be set, wall boundary properties may be set, physical parameters of an inlet and an outlet may be set, parameters of an inlet fluid may be set as a mixture gas model based on empirical formula, physical properties of a mixture gas may be set using an empirical formula model, and a density of the mixture gas may be determined using an incompressible ideal gas manner, i.e.:

$${ρ}_{m} = \frac{{P}_{op} \cdot {M}_{w}}{R \cdot T} \qquad ( 1 )$$

where R denotes a universal gas constant; M_{w} denotes a molecular weight of the gas; Pₒₚ denotes the operation pressure, and T denotes a thermodynamic temperature of the gas mixture;
   Steam may be generated during the transport of coal powder, so a fluid flowing in the flow equalization air ring structure in the coal mill may be a mixer of air and water vapor. The diffusivity of the gas mixture is related to temperature and pressure. Therefore, an empirical correlation equation related to the temperature and pressure may be used:

$${D}_{m} = \frac{9.26 \times {10}^{- 5}}{P} \cdot \frac{{T}^{2.5}}{( T + 245 )} \qquad ( 2 )$$

where P denotes a pressure of the gas mixture; and T denotes the thermodynamic temperature of the gas mixture.

The pressure has little effect on the thermal conductivity of water vapor, so the thermal conductivity may be determined according to a temperature-dependent fitting equation:

$${λ}_{v} = 0.02682 - 1.202 \times {10}^{- 4} T + 3.1 \times 10 - 7 {T}^{2} \qquad ( 3 )$$

As the pressure changes, a change of a constant-pressure specific heat is relatively small, so the constant-pressure specific heat may be determined according to a temperature-dependent empirical correlation equation:

$${c}_{p , v} = 5998 - 25.12 T + 0.03917 {T}^{2} \qquad ( 4 )$$

S6: computation information of a mesh node may be initialized according to a working condition and a global initialization scheme for a computation region may be adopted.

S7: a residual curve to be monitored in computation may be determined, a monitoring curve may be established based on a total mass flow rate at an inlet and outlet of a flow field, a total number of computation steps and computation step size of the energy equation model may be set. In this embodiment, a total computation duration may be set to 60 seconds and a time step size may be set in a range of 0.001 seconds to 0.01 seconds. Therefore, the total number of computation steps may be in a range of 60,000 steps and 6,000 steps. The total number of computation steps may be determined as 60 divided by the time step size. The solution may then be iteratively solved to obtain a computation result;

In S8: whether a computation process is convergent may be judged based on the residual curve, the computation result, and the total mass flow rate at the inlet and outlet of the flow field, in response to judging the computation process being convergent, post-processing may be performed on the computation result to obtain a distribution result of parameters of the flow field; and in response to judging the computation process being not convergent, the meshes, the energy equation model, and the boundary condition may be adjusted, and re-computation may be performed until the computation process converges. The distribution result of parameters of the flow field may include a velocity, pressure, temperature, and heat-transfer coefficient of the flow field. In the S8, the heat transfer between a solid structure of the model of the flow equalization air ring structure and the fluid may be primarily through convective heat transfer, an equation is shown as follows:

$$h = \frac{{q}_{w}}{{T}_{surf} - {T}_{w}} \qquad ( 5 )$$

where q_{w} denotes a heat flux density value extracted from a wall in Ansys Fluent, T_{surf} denotes a temperature value of a computation cell at a height position of the boundary layer in the flow domain, and Tw denotes a temperature value of the wall.

In S9: a computation result after the computation process is convergent may be stored;

In S10: parameters of the flow equalization air ring structure in the medium-speed coal miller may be modified, and after completion of modification, the S1 to S9 may be repeated to obtain a plurality of simulation results, and the plurality of simulation results may be compared to obtain parameters of an optimal flow equalization air ring structure to complete the optimization process.

### Embodiment 2

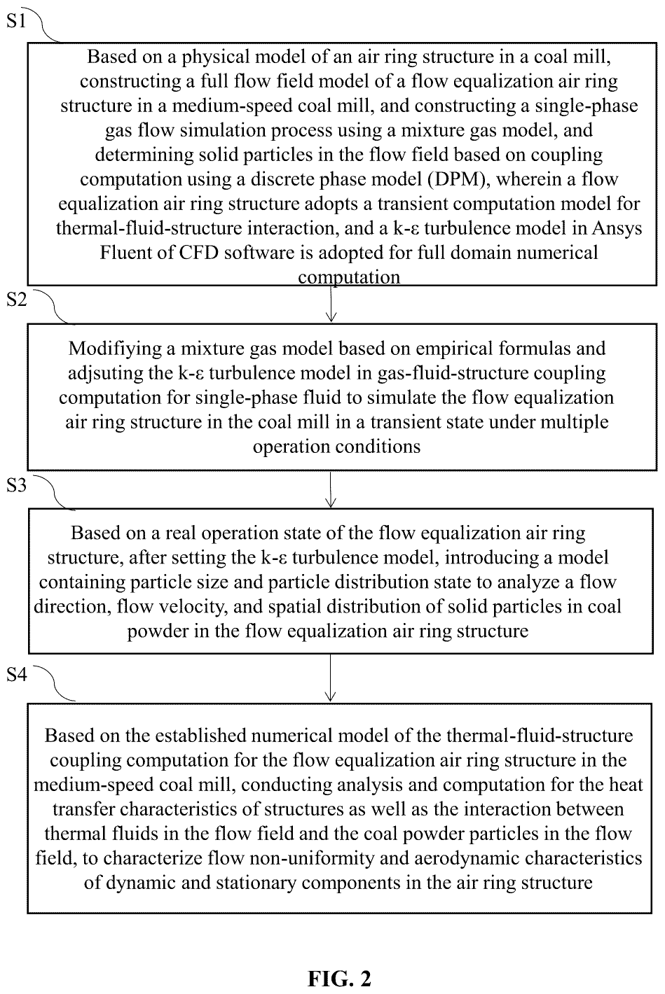

This embodiment is described with reference to FIG. 2.

The present embodiment is a further example of the method for optimizing aerodynamic characteristics of the flow equalization air ring structure in the medium-speed coal mill based on Fluent simulation described in the Embodiment 1.

Operations of the method described herein may include:

In operation 1: based on a physical model of an air ring structure in a coal mill, a full flow field model of a flow equalization air ring structure in a medium-speed coal mill may be constructed, and a single-phase gas flow simulation process may be constructed using a mixture gas model, and solid particles in the flow field may be determined based on coupling computation using a discrete phase model (DPM). A thermal-fluid-solid coupling transient calculation model for air ring flow equalization structure adopts a k-εturbulence model in Ansys Fluent of CFD software for full domain numerical computation.

Specifically, the model of the flow equalization air ring structure in the medium-speed coal mill may be established using a general 3D modeling software UG and the model may be stored in STP format, and a portion of the air ring structure that does not affect the flow field may be optimized using an Ansys SpaceClaim software, and computation resources may be saved. A hot air flow field in the air ring structure may be constructed using a flow field extraction function. Through the above operations, the flow equalization air ring structure and a solid structure in the medium-speed coal mill may be obtained, and a rotating ring region and a stationary ring region of the model of the flow equalization air ring structure may be drawn and named, respectively.

General functions in Ansys Fluent may be set, a pressure-based solution model may be selected, and a scale of the model, a magnitude and direction of gravitational acceleration, and a coupling mode for velocity and pressure may be set, and computation may be set to a transient state mode.

In a turbulence modeling process, the k-εturbulence model may be selected, and the Re-Normalization Group (RNG) model may be selected.

An input equation of the RNGk-εturbulence model may be expressed as follows:

$$\frac{\partial }{\partial t} ( ρ k ) + \frac{\partial }{{\partial }_{{x}_{i}}} ( ρ {ku}_{i} ) = \frac{\partial }{{\partial }_{{x}_{j}}} ( {a}_{k} {u}_{eff} \frac{{\partial }_{k}}{{\partial }_{{x}_{j}}} ) + {G}_{k} + {G}_{b} - ρε - {Y}_{M} + {S}_{k} \\ \frac{\partial }{\partial t} ( ρε ) + \frac{\partial }{{\partial }_{{x}_{i}}} ( ρε {u}_{i} ) = \frac{\partial }{{\partial }_{{x}_{j}}} ( {a}_{ε} {u}_{eff} \frac{{\partial }_{ε}}{{\partial }_{{x}_{j}}} ) + ( {G}_{k} + {C}_{3 ε} {G}_{b} ) - {C}_{3 ε} ρ \frac{{ε}^{2}}{k} - {R}_{ε} + {S}_{ε} \qquad ( 6 )$$

In the equation, Gₖ denotes a turbulence kinetic energy generated by the mean velocity gradient, which may be calculated based on the turbulence generation model in the k-εmodel, G_{b} denotes a turbulence kinetic energy generated by buoyancy, which may be calculated based on the influence of buoyancy on turbulence in the k-εmodel, and Y_{M} denotes a contribution of fluctuating expansion in compressible turbulence to the total dissipation rate, which may be calculated based on the influence of compressibility on turbulence in the k-εmodelₖ and a_{ε} correspond to inverse effective Prandtl numbers for k and ε, respectively, and Sₖ and S_{ε} denote user-defined source terms. The turbulent viscosity obtained from the dimensionless process in the RNG theory may be obtained using a following equation:

$$d ( \frac{\begin{matrix}ρ & {}^{2} k\end{matrix}}{\sqrt{εμ}} ) = 1.72 \frac{\hat{v}}{\sqrt{{\hat{v}}^{3} - 1 {C}_{v}}} \qquad ( 7 )$$

where \hat{v} may be expressed by a following equation:

$$\hat{v} = \frac{{u}_{eff}}{u} \qquad ( 8 )$$

where Cᵥ may be taken as 100 during the computation.

Since a fluid velocity in the dynamic and stationary air ring in a coal mill is relatively high, for a computation manner under a high Reynolds number condition, a viscosity computation equation as follow may be added:

$${u}_{t} = ρ {C}_{u} \frac{{k}^{2}}{ε} \qquad ( 9 )$$

where C_{μ} may be taken as 0.00845.

In operation 2: the mixture gas model may be modified based on empirical equations and the k-εturbulence model in gas-fluid-structure coupling computation for single-phase fluid may be adjusted to simulate the flow equalization air ring structure in the coal mill in a transient state under multiple operation conditions.

Specifically: due to the large amount of water vapor volatilized by coal powder in the coal mill, the air flowing in the air ring structure contains moisture. Therefore, the fluid in the flow field is a mixture of air and water vapor. When setting fluid properties at the inlet and the outlet, a density of the mixture may be determined using an incompressible ideal gas manner:

$${ρ}_{m} = \frac{{P}_{op} \cdot {M}_{w}}{R \cdot T} \qquad ( 10 )$$

A diffusivity of the gas mixture is related to temperature and pressure, therefore, an empirical correlation equation related to the temperature and pressure may be used:

$${D}_{m} = \frac{9.26 \times {10}^{- 5}}{P} \cdot \frac{{T}^{2.5}}{( T + 245 )} \qquad ( 11 )$$

The pressure has little effect on the thermal conductivity of water vapor, so the thermal conductivity may be determined according to a temperature-dependent fitting equation:

$${λ}_{v} = 0.02682 - 1.202 \times {10}^{- 4} T + 3.1 \times {10}^{- 7} {T}^{2} \qquad ( 12 )$$

As the pressure changes, the specific heat at constant pressure changes less, so the specific heat at constant pressure may be determined according to the temperature-dependent empirical correlation equation:

$${c}_{p , v} = 5998 - 25.12 T + 0.03917 {T}^{2} \qquad ( 13 )$$

Parameters in the k-εmodel may be adjusted to make the model applicable to computation conditions.

In operation 3: based on a real operation state of the flow equalization air ring structure, after setting the k-εturbulence model, a model containing particle size and particle distribution state may be introduced to analyze a flow direction, flow velocity, and spatial distribution of solid particles in coal powder in the flow equalization air ring structure.

Specifically, in a model setting, the discrete phase model (DPS) may be enabled to activate the interaction model between the discrete phase and the continuous phase. A particle injection source may be created, the injection type may be selected as a surface injection, and the fluid inlet surface may be selected as the release surface. Inert particles may be selected as the particle type, which may not react due to heat transfer, designed coal powder particles may be selected as the particle material properties, and a Rosin-Rammler distribution may be selected as the particle size distribution, and distribution parameters of the Rosin-Rammler distribution may be obtained through experiments and subsequently determined according to a fragmentation equation:

$${R}_{x} = 100 {e}^{- {bx}^{n}} \qquad ( 14 )$$

wherein Rₓ denotes a sieve residue on a sieve with a mesh size of x μm, b denotes a coefficient characterizing a fineness of the coal powder, and n denotes a uniformity index of the coal powder.

The particle size distribution may be set based on a minimum particle size, a maximum particle size, an average particle size, a diffusion coefficient, and a count of particles according to the fineness of the coal powder obtained from experiments. For a certain coal mill, b and n may be set as constants when x is in a range of 60 μm to 200 μm.

In operation 4: based on the established numerical model of the thermal-fluid-structure coupling computation for the flow equalization air ring structure in the medium-speed coal mill, analysis and computation may be conducted for the heat transfer characteristics of structures as well as the interaction between thermal fluids in the flow field and the coal powder particles in the flow field, to characterize flow non-uniformity and aerodynamic characteristics of dynamic and stationary components in the air ring structure.

Specifically, for a computed fluid region, a fluid region of the dynamic air ring structure may be set as a multiple reference frame (MRF) rotating region. A rotating fluid region may be selected as Frame Motion, and a fluid medium in the region may be set as a mixture gas, and rotation center coordinates, rotation direction, and rotational angular velocity of the dynamic air ring structure under operation conditions may also be set. The computation for all computational regions may be initialized, and iterative computation may be performed. In response to determining that a computation result converges, a temperature, velocity, and pressure of the flow field may be analyzed, and movement trajectories of particles may be analyzed.

### Embodiment 3

The present embodiment proposes a system for optimizing aerodynamic characteristics of a flow equalization air ring structure in a medium-speed coal mill based on Fluent simulation. The system comprises the following modules:
a modeling module: configured to determine a flow equalization air ring structure in a coal mill and establish a model of the flow equalization air ring structure;
a meshing module: configured to mesh the model of the flow equalization air ring structure;
a checking module: configured to check meshes and set mesh parameters;
a selection module: configured to select an energy equation model, and set a turbulence model and a Discrete Phase Model (DPM);
a condition module: configured to set a boundary condition;
an initializing module: configured to initialize computation information of a mesh node;
a computation module: configured to set a residual curve, establish a monitoring curve based on a total mass flow rate at an inlet and outlet of a flow field, set a total number of computation steps and computation step size of the energy equation model, and perform iterative solving to obtain a computation result;
a judgment module: configured to judge whether a computation process is convergent based on the residual curve, the computation result, and the total mass flow rate at the inlet and outlet of the flow field, in response to judging the computation process being convergent, perform post-processing on the computation result to obtain a distribution result of parameters of the flow field; and in response to judging the computation process being not convergent, adjust the meshes, the energy equation model, and the boundary condition, and re-calculate until the computation process converges;
a storage module: configured to save a computation result after the computation process is convergent; and
an optimization module: configured to modify parameters of the flow equalization air ring structure in the medium-speed coal miller, and after completion of modification, repeat steps of the modules to obtain a plurality of simulation results, compare the plurality of simulation results to obtain parameters of an optimal flow equalization air ring structure, and complete optimization.

The skilled person in this field will understand that the above description is merely a preferred embodiment of the present invention. The features described in the various embodiments and/or claims of this disclosure may be combined or incorporated in various ways, even if such combinations or incorporations are not explicitly mentioned in the present disclosure and are not intended to limit the invention. Although the invention has been described in detail with reference to the aforementioned embodiments, those skilled in the art can still modify the technical solutions described in the various embodiments or equivalently substitute some of the technical features. Any modifications, equivalent substitutions, or improvements made within the spirit and principle of the invention shall be included within the protection scope of the present disclosure.

Clearly, those skilled in the art can make various alterations and modifications to the present invention without departing from the spirit and scope of the invention. Thus, if such modifications and variations of the invention fall within the scope of the claims and their equivalents, the invention is intended to encompass these alterations and modifications as well.

Obviously, a person skilled in the art can make various changes and variations to the present invention without departing from the spirit and scope of the present invention. As such, the present invention is intended to encompass these modifications and variations if they fall within the scope of the claims of the present invention and their technical equivalents.

Those skilled in the art should understand that the embodiments disclosed herein may be provided as methods, systems, or computer program products. Therefore, the present disclosure can be implemented in the form of entirely hardware-based embodiments, entirely software-based embodiments, or embodiments combining both software and hardware aspects. Furthermore, the present disclosure can be implemented in the form of a computer program product on one or more computer-readable storage media (including but not limited to disk storage, CD-ROMs, optical storage, etc.) containing computer-readable program code.

The disclosure is described with reference to the flowcharts and/or block diagrams of methods, devices (systems), and computer program products according to the embodiments disclosed herein. It should be understood that each process and/or block in the flowchart and/or block diagram, as well as the combination of processes and/or blocks in the flowchart and/or block diagram, can be implemented by computer program instructions. These computer program instructions may be provided to a general-purpose computer, dedicated computer, embedded processor, or other programmable data processing device's processor to create a machine, such that the instructions executed by the processor of the computer or other programmable data processing device produce a device for performing the functions specified in one or more processes in the flowchart or one or more blocks in the block diagram. These computer program instructions may also be stored in a computer-readable storage medium that directs a computer or other programmable data processing device to operate in a specific way, such that the instructions stored in the computer-readable storage medium produce a manufactured device, including an instruction device, that performs the functions specified in one or more processes in the flowchart or one or more blocks in the block diagram.

These computer program instructions may also be loaded onto a computer or other programmable data processing device, such that executing a series of operations on the computer or other programmable device results in computer-implemented processing, thereby providing steps for performing the functions specified in one or more processes in the flowchart or one or more blocks in the block diagram through the instructions executed on the computer or other programmable device.

It should be noted that the above embodiments are only for illustrating the technical solutions of the present disclosure and are not intended to limit the scope of protection. Although the disclosure has been described in detail with reference to the above embodiments, those skilled in the art should understand that after reading the disclosure, they can still make various changes, modifications, or equivalent substitutions to the specific embodiments of the invention. However, these changes, modifications, or equivalent substitutions are within the scope of the claims awaiting approval.

What is claimed is:

1. A method for optimizing aerodynamic characteristics of a flow equalization air ring structure in a medium-speed coal mill based on Fluent simulation, the method comprising:
S1: determining a flow equalization air ring structure in a coal mill and establishing a model of the flow equalization air ring structure;
S2: meshing the model of the flow equalization air ring structure;
S3: checking meshes and setting mesh parameters;
S4: selecting an energy equation model, and setting a turbulence model and a Discrete Phase Model (DPM);
S5: setting a boundary condition;
S6: initializing computation information of a mesh node;
S7: setting a residual curve, establishing a monitoring curve based on a total mass flow rate at an inlet and outlet of a flow field, setting a total number of computation steps and computation step size of the energy equation model, and performing iterative solving to obtain a computation result;
S8: judging whether a computation process is convergent based on the residual curve, the computation result, and the total mass flow rate at the inlet and outlet of the flow field, in response to judging the computation process being convergent, performing post-processing on the computation result to obtain a distribution result of parameters of the flow field; and in response to judging the computation process being not convergent, adjusting the meshes, the energy equation model, and the boundary condition, and re-calculating until the computation process converges;
S9: storing a computation result after the computation process is convergent; and
S10: modifying parameters of the flow equalization air ring structure in the medium-speed coal miller, and after completion of modification, repeating S1 to S9 to obtain a plurality of simulation results, comparing the plurality of simulation results to obtain parameters of an optimal flow equalization air ring structure, and completing the method.

2. The method of claim 1, wherein in the S1, the model of the flow equalization air ring structure is established based on an outer diameter, an inner diameter, a size of a flow equalization unit, a count of the flow equalization unit, and an inlet wind angle of the flow equalization air ring structure.

3. The method of claim 1, wherein the S1 further includes importing the model of the flow equalization air ring structure into Ansys SpaceClaim to optimize a structure and a flow field domain model of the flow equalization air ring structure, and dividing and naming a rotating ring region and a stationary ring region of the model of the flow equalization air ring structure, respectively.

4. The method of claim 1, wherein the S2 includes dividing an overall flow field of the model of the flow equalization air ring structure using a tetrahedral mesh, adding a hexahedral boundary layer at a fluid near-wall region and naming different regions of the hexahedral boundary layer after addition, respectively.

5. The method of claim 1, wherein the checking meshes include checking quality, size, and distribution state of the meshes; and the mesh parameters include mesh size, pressure velocity, and gravity direction.

6. The method of claim 1, wherein the S5 includes: setting a fluid region, and a fluid region of a dynamic ring structure is arranged with a Multiple Reference Frame (MRF) rotating region, setting a material of the MRF rotating region, properties of a wall condition, and physical parameters of an inlet and outlet.

7. The method of claim 6, wherein particle distribution parameters of the DPM are calculated using a fragmentation formula.

8. A computer device, comprising a memory and a processor, wherein the memory stores a computer program, and when the processor executes the computer program stored in the memory, the processor executes the method of claim 1.

9. A computer-readable storage medium, wherein the storage medium stores a computer program, and the computer program executes steps of the method of claim 1.

10. A system for optimizing aerodynamic characteristics of a flow equalization air ring structure in a medium-speed coal mill based on Fluent simulation, the system comprising:
a modeling module: configured to determine a flow equalization air ring structure in a coal mill and establish a model of the flow equalization air ring structure;
a meshing module: configured to mesh the model of the flow equalization air ring structure;
a checking module: configured to check meshes and set mesh parameters;
a selection module: configured to select an energy equation model, and set a turbulence model and a Discrete Phase Model (DPM);
a condition module: configured to set a boundary condition;
an initializing module: configured to initialize computation information of a mesh node;
a computation module: configured to set a residual curve, establish a monitoring curve based on a total mass flow rate at an inlet and outlet of a flow field, set a total number of computation steps and computation step size of the energy equation model, and perform iterative solving to obtain a computation result;
a judgment module: configured to judge whether a computation process is convergent based on the residual curve, the computation result, and the total mass flow rate at the inlet and outlet of the flow field, in response to judging the computation process being convergent, perform post-processing on the computation result to obtain a distribution result of parameters of the flow field; and in response to judging the computation process being not convergent, adjust the meshes, the energy equation model, and the boundary condition, and re-calculate until the computation process converges;
a storage module: configured to save a computation result after the computation process is convergent; and
an optimization module: configured to modify parameters of the flow equalization air ring structure in the medium-speed coal miller, and after completion of modification, repeat steps of the modules to obtain a plurality of simulation results, compare the plurality of simulation results to obtain parameters of an optimal flow equalization air ring structure, and complete optimization.
